(19) United States
(12) Patent Application Publication
(10) Pub. No.: US 2008/0149913 A1
(43) Pub. Date: Jun. 26, 2008

(54) SEMICONDUCTOR MEMORY DEVICE AND METHOD OF MANUFACTURING THE SAME

(76) Inventors: Hiroyasu TANAKA, Tokyo (JP); Ryota Katsumata, Yokohama-shi (JP); Hideaki Aochi, Kawasaki-shi (JP); Masaru Kito, Yokohama-shi (JP); Masaru Kidoh, Kawasaki-shi (JP); Mitsuru Sato, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/962,862

(22) Filed: Dec. 21, 2007

(30) Foreign Application Priority Data
Dec. 26, 2006 (JP) 2006-349538

(51) Int. Cl. H01L 27/105; H01L 21/8239; H01L 45/00

(52) U.S. Cl. 257/5; 438/238; 257/379; 257/E21.645; 257/E27.081; 257/E45.002

(57) ABSTRACT

A semiconductor memory device is disclosed, which includes a first memory cell array formed on a semiconductor substrate and composed of a plurality of memory cells stacked in layers each having a characteristic change element and a vertical type memory cell transistor connected in parallel to each other, a plurality of second memory cell arrays formed on the semiconductor substrate and having the same structure as the first memory cell array, and arranged in an X direction with respect to the first memory cell array, and a plurality of third memory cell arrays formed on the semiconductor substrate and having the same structure as the first memory cell array, and arranged in a Y direction with respect to the first memory cell array, wherein a gate voltage is applied to gates of the vertical type memory cell transistors of the first to third memory cell arrays in a same layer.

### CROSS-REFERENCE TO RELATED APPLICATIONS

This application is based upon and claims the benefit of priority from prior Japanese Patent Application No. 2006-349538, filed Dec. 26, 2006, the entire contents of which are incorporated herein by reference.

### BACKGROUND OF THE INVENTION

1. Field of the Invention

The present invention relates to a semiconductor memory device, and to a method of manufacturing the same.

2. Description of the Related Art

A next-generation non-volatile memory has been developed, and has the following features. The next-generation non-volatile memory is rewritable at high speed as compared with conventional EEPROM and flash memory. In addition, the number of rewritable times is larger than five digits. The next-generation non-volatile memory is developed for the purpose of realizing the capacity equivalent to DRAM, speed and cost. For example, FeRAM (Ferroelectric Random Access Memory), MRAM (Magnetic Random Access Memory), PRAM (Phase change Random Access Memory) or RRAM (resistive Random Access Memory) are given as the next-generation non-volatile memory. In the PRAM (phase change memory), a memory cell is composed of a phase change element and a transistor (E.g., see Jpn. Pat. Appln. KOKAI Publication No. 2004-158854 (page 14, FIG. 1 and FIG. 2).

Scale reduction in the plane direction of a phase change element and a transistor is necessary in order to achieve high integration of a memory cell of the PRAM (phase change memory) described in the foregoing Publication No. 2004-158854 (page 14, FIG. 1 and FIG. 2). However, the PRAM has the following problems. Specifically, there is a physical limit due to lithography limit to achieve the scale reduction of the plan direction. In addition, if the scale reduction of the memory cell is achieved, phase change element and transistor characteristics are reduced; as a result, desired characteristic is not maintained. Moreover, RRAM has the same problems as above.

### BRIEF SUMMARY OF THE INVENTION

According to a first aspect of the present invention, there is provided a semiconductor memory device comprising:

a first memory cell array formed on a semiconductor substrate and composed of a plurality of memory cells stacked in layers each having a characteristic change element and a vertical type memory cell transistor connected in parallel to each other;

a plurality of second memory cell arrays formed on the semiconductor substrate and having the same structure as the first memory cell array, and arranged in an X direction with respect to the first memory cell array; and

a plurality of third memory cell arrays formed on the semiconductor substrate and having the same structure as the first memory cell array, and arranged in a Y direction with respect to the first memory cell array, wherein

a gate voltage is applied to gates of the vertical type memory cell transistors of the first to third memory cell arrays in a same layer.

According to a second aspect of the present invention, there is provided a semiconductor memory device comprising:

a memory cell array including:

a vertical type select transistor formed on a semiconductor substrate, and having one of source and drain connected to a source line and having a gate connected to a word line; and

a plurality of memory cells stacked in layers on the vertical type select transistor, and interposed between a bit line and the other of source and drain of the vertical type select transistor, each of the memory cells having a characteristic change element and a vertical type memory cell transistor connected in parallel to each other, wherein

a gate of the vertical type memory cell transistor is connected to a gate driver transistor.

According to a third aspect of the present invention, there is provided a method of manufacturing a semiconductor memory device including a plurality of memory cells stacked in layers formed on a semiconductor substrate, each of the memory cells being composed of a characteristic change element and a vertical type memory cell transistor connected in parallel to each other, comprising:

forming a plurality of stacked film structures on a surface of a semiconductor substrate, each including a first silicon film and an interlayer insulating film, and selectively etching the stacked film structures to form an opening in the stacked film structures;

etching sides of the first silicon films exposed in the opening to retreat the sides of the first silicon films from sides of the interlayer insulating films;

forming gate insulating films on the retreated sides of the first silicon films;

forming a second silicon film, an anti-reaction film, a characteristic change film and a first insulating film in the order, after the forming of the gate insulating films;

polishing the first insulating film, the characteristic change film, the anti-reaction film and the second silicon film above the surface of the semiconductor substrate to form the first insulating film, the characteristic change film, the anti-reaction film and the second silicon film embedded in the opening;

etching back an uppermost interlayer insulating film by a predetermined thickness to expose upper surfaces of the second silicon film and the characteristic change film; and

forming a third silicon film on the exposed second silicon film and the characteristic change film.

### BRIEF DESCRIPTION OF THE SEVERAL VIEWS OF THE DRAWING

FIG. 1 is a perspective view showing a structure of a semiconductor memory device according to a first embodiment of the present invention.

FIG. 2 is a cross-sectional view of the semiconductor memory device shown in FIG. 1, taken along the line A-A of FIG. 1.

FIG. 3 is a cross-sectional view of the semiconductor memory device shown in FIG. 1, taken along the line B-B of FIG. 1.

FIG. 4 is a cross-sectional view of a memory cell portion of the semiconductor memory device according to the first embodiment of the present invention.

FIG. 5 is a cross-sectional view showing one memory cell of the semiconductor memory device shown in FIG. 4.

FIG. 6 is a view showing an equivalent circuit diagram of the semiconductor memory device shown in FIG. 4.

FIG. 7 is an equivalent circuit diagram to explain an operation of the semiconductor memory device according to the first embodiment of the present invention.

FIG. 8 is a table to explain an operation of the semiconductor memory device according to the first embodiment of the present invention.

FIG. 9 is a plan view of a semiconductor memory device in a step of a manufacturing method according to the first embodiment of the present invention.

FIG. 10 is a cross-sectional view of the semiconductor memory device shown in FIG. 9, taken along the line C-C of FIG. 9.

FIG. 11 is a cross-sectional view of the semiconductor memory device shown in FIG. 9, taken along the line D-D of FIG. 9.

FIG. 12 is a plan view of a semiconductor memory device in a step of the manufacturing method according to the first embodiment of the present invention.

FIG. 13 is a cross-sectional view of the semiconductor memory device shown in FIG. 12, taken along the line C-C of FIG. 12.

FIG. 14 is a cross-sectional view of the semiconductor memory device shown in FIG. 12, taken along the line D-D of FIG. 12.

FIG. 15 is a plan view of a semiconductor memory device in a step of the manufacturing method according to the first embodiment of the present invention.

FIG. 16 is a cross-sectional view of the semiconductor memory device shown in FIG. 15, taken along the line C-C of FIG. 15.

FIG. 17 is a cross-sectional view of the semiconductor memory device shown in FIG. 15, taken along the line D-D of FIG. 15.

FIG. 18 is a plan view of a semiconductor memory device in a step of the manufacturing method according to the first embodiment of the present invention.

FIG. 19 is a cross-sectional view of the semiconductor memory device shown in FIG. 18, taken along the line C-C of FIG. 18.

FIG. 20 is a cross-sectional view of the semiconductor memory device shown in FIG. 18, taken along the line D-D of FIG. 18.

FIG. 21 is a plan view of a semiconductor memory device in a step of the manufacturing method according to the first embodiment of the present invention.

FIG. 22 is a cross-sectional view of the semiconductor memory device shown in FIG. 21, taken along the line C-C of FIG. 21.

FIG. 23 is a cross-sectional view of the semiconductor memory device shown in FIG. 21, taken along the line D-D of FIG. 21.

FIG. 24 is a plan view of a semiconductor memory device in a step of the manufacturing method according to the first embodiment of the present invention.

FIG. 25 is a cross-sectional view of the semiconductor memory device shown in FIG. 24, taken along the line C-C of FIG. 24.

FIG. 26 is a cross-sectional view of the semiconductor memory device shown in FIG. 24, taken along the line D-D of FIG. 24.

FIG. 27 is a plan view of a semiconductor memory device in a step of the manufacturing method according to the first embodiment of the present invention.

FIG. 28 is a cross-sectional view of the semiconductor memory device shown in FIG. 27, taken along the line C-C of FIG. 27.

FIG. 29 is a cross-sectional view of the semiconductor memory device shown in FIG. 27, taken along the line D-D of FIG. 27.

FIG. 30 is a plan view of a semiconductor memory device in a step of the manufacturing method according to the first embodiment of the present invention.

FIG. 31 is a cross-sectional view of the semiconductor memory device shown in FIG. 30, taken along the line C-C of FIG. 30.

FIG. 32 is a cross-sectional view of the semiconductor memory device shown in FIG. 30, taken along the line D-D of FIG. 30.

FIG. 33 is a plan view of a semiconductor memory device in a step of the manufacturing method according to the first embodiment of the present invention.

FIG. 34 is a cross-sectional view of the semiconductor memory device shown in FIG. 33, taken along the line C-C of FIG. 33.

FIG. 35 is a cross-sectional view of the semiconductor memory device shown in FIG. 33, taken along the line D-D of FIG. 33.

FIG. 36 is a plan view of a semiconductor memory device in a step of the manufacturing method according to the first embodiment of the present invention.

FIG. 37 is a cross-sectional view of the semiconductor memory device shown in FIG. 36, taken along the line C-C of FIG. 36.

FIG. 38 is a cross-sectional view of the semiconductor memory device shown in FIG. 36, taken along the line D-D of FIG. 36.

FIG. 39 is a plan view of a semiconductor memory device in a step of the manufacturing method according to the first embodiment of the present invention.

FIG. 40 is a cross-sectional view of the semiconductor memory device shown in FIG. 39, taken along the line C-C of FIG. 39.

FIG. 41 is a cross-sectional view of the semiconductor memory device shown in FIG. 39, taken along the line D-D of FIG. 39.

FIG. 42 is a plan view of a semiconductor memory device in a step of the manufacturing method according to the first embodiment of the present invention.

FIG. 43 is a cross-sectional view of the semiconductor memory device shown in FIG. 42, taken along the line C-C of FIG. 42.

FIG. 44 is a cross-sectional view of the semiconductor memory device shown in FIG. 42, taken along the line D-D of FIG. 42.

FIG. 45 is a plan view of a semiconductor memory device in a step of the manufacturing method according to the first embodiment of the present invention.

FIG. 46 is a cross-sectional view of the semiconductor memory device shown in FIG. 45, taken along the line C-C of FIG. 45.

FIG. 47 is a cross-sectional view of the semiconductor memory device shown in FIG. 45, taken along the line D-D of FIG. 45.

FIG. 48 is a cross-sectional view of a memory cell portion of a semiconductor memory device according to a second embodiment of the present invention.

FIG. 49 is a cross-sectional view showing one memory cell of the semiconductor memory device shown in FIG. 48.

FIG. 50 is a view showing an equivalent circuit diagram of the semiconductor memory device shown in FIG. 48.

FIG. 51 is a plan view of a semiconductor memory device in a step of a manufacturing method according to the second embodiment of the present invention.

FIG. 52 is a cross-sectional view of the semiconductor memory device shown in FIG. 51, taken along the line C-C of FIG. 51.

FIG. 53 is a cross-sectional view of the semiconductor memory device shown in FIG. 51, taken along the line D-D of FIG. 51.

FIG. 54 is a plan view of a semiconductor memory device in a step of the manufacturing method according to the second embodiment of the present invention.

FIG. 55 is a cross-sectional view of the semiconductor memory device shown in FIG. 54, taken along the line C-C of FIG. 54.

FIG. 56 is a cross-sectional view of the semiconductor memory device shown in FIG. 54, taken along the line D-D of FIG. 54.

FIG. 57 is a plan view of a semiconductor memory device in a step of the manufacturing method according to the second embodiment of the present invention.

FIG. 58 is a cross-sectional view of the semiconductor memory device shown in FIG. 57, taken along the line C-C of FIG. 57.

FIG. 59 is a cross-sectional view of the semiconductor memory device shown in FIG. 57, taken along the line D-D of FIG. 57.

FIG. 60 is a plan view of a semiconductor memory device in a step of the manufacturing method according to the second embodiment of the present invention.

FIG. 61 is a cross-sectional view of the semiconductor memory device shown in FIG. 60, taken along the line C-C of FIG. 60.

FIG. 62 is a cross-sectional view of the semiconductor memory device shown in FIG. 60, taken along the line D-D of FIG. 60.

### DETAILED DESCRIPTION OF THE INVENTION

Various embodiments of the present invention will be hereinafter described with reference to the accompanying drawings.

### First Embodiment

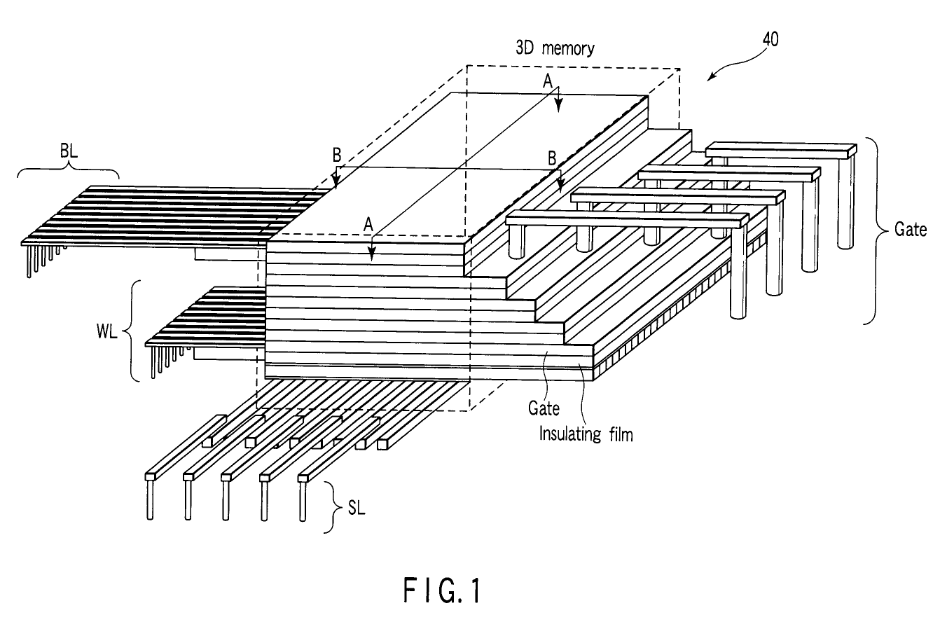

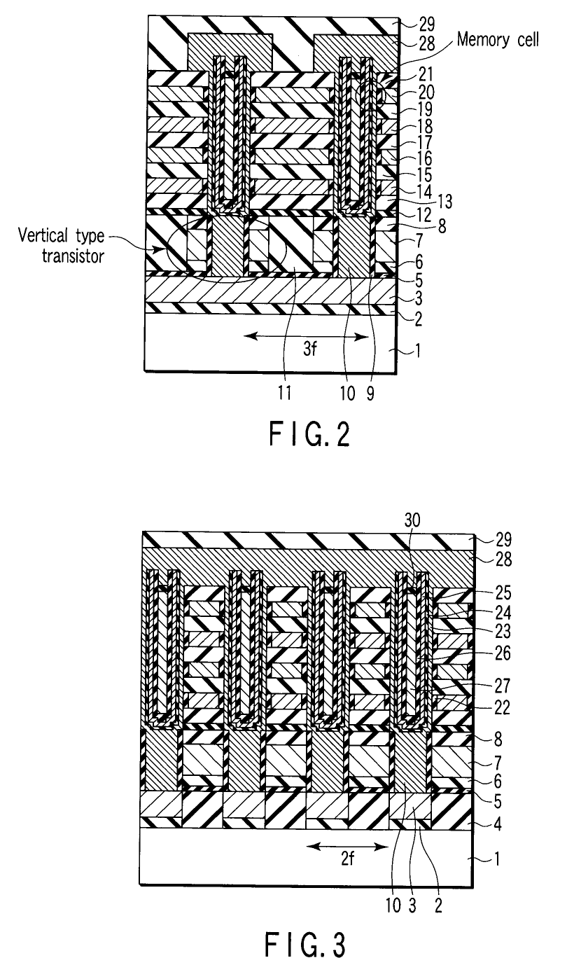

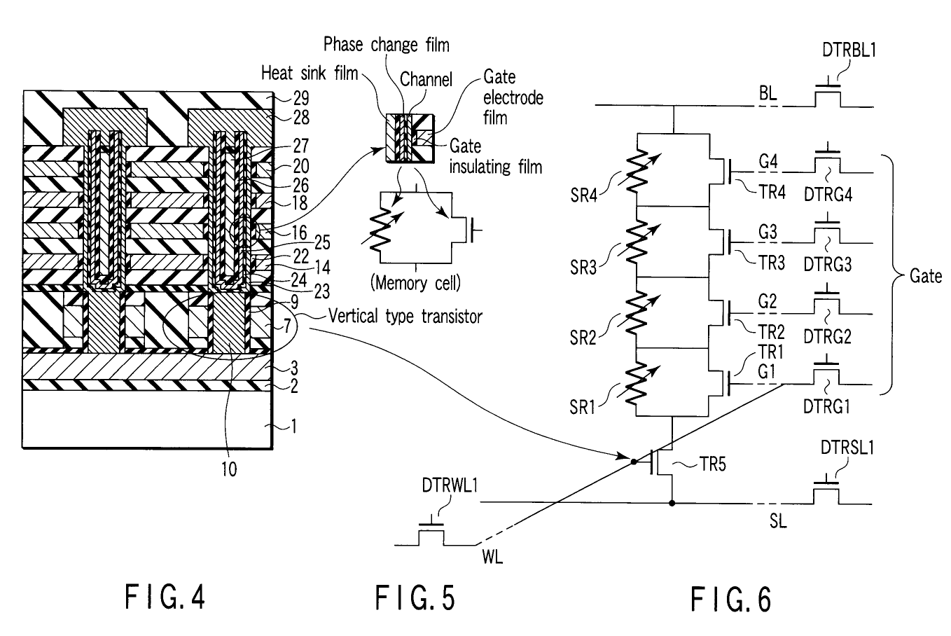

A semiconductor memory device and a method of manufacturing the same according to a first embodiment of the present invention will be hereinafter described with reference to the accompanying drawings. FIG. 1 is a perspective view showing a structure of a semiconductor memory device according to a first embodiment of the present invention. FIG. 2 is a cross-sectional view of the semiconductor memory device shown in FIG. 1, taken along the line A-A of FIG. 1. FIG. 3 is a cross-sectional view of the semiconductor memory device shown in FIG. 1, taken along the line B-B of FIG. 1. FIG. 4 is a cross-sectional view of a memory cell portion of the semiconductor memory device according to the first embodiment of the present invention. FIG. 5 is a cross-sectional view showing one memory cell of the semiconductor memory device shown in FIG. 4. FIG. 6 is a view showing an equivalent circuit diagram of the semiconductor memory device shown in FIG. 4. In the first embodiment, a plurality of phase change memory cells is stacked on a semiconductor substrate to form a three-dimensional memory cell portion.

As shown in FIG. 1, a phase change memory 40 functioning as a semiconductor memory device is a three-dimensional PRAM (Phase Change Random Access Memory). In the phase change memory 40, a plurality of memory cells (1 bit) is stacked on a semiconductor substrate. Each of the memory cells comprises a phase change element and a memory cell transistor. In this embodiment, illustration and explanation of lead portion and input/output portion of the memory cell of the phase change memory 40 are omitted.

A plurality of source lines SL is provided in parallel to each other on the side of the semiconductor substrate. A plurality of word lines WL is provided in parallel to each other above the source lines SL to cross the source lines SL. A plurality of bit lines BL is provided in parallel to each other on the upper part of the memory cell portion to cross the source lines SL. Gates (Gate) of memory cell transistors are isolated via insulating films, and extended in a direction reverse to the bit lines. The source lines SL, word lines WL, bit lines BL and gates Gate are connected to respective interconnect layers by respective vias.

As illustrated in FIG. 2 and FIG. 3, an insulating film 2 as an interlayer insulating film is formed on a semiconductor substrate 1, and a plurality of interconnect layers 3 are selectively formed on the insulating film 2. An insulating film 4 as an interlayer insulating film is buried between adjacent interconnect layers 3. A silicon film 7 is formed on the interconnect layer 3 via insulating films 5 and 6. An insulating film 8 is formed on the silicon film 7. A gate insulating film 9 contacting with the silicon film 7 and a silicon film 10 contacting with the gate insulating film 9 are buried on one side of the silicon film 7, as shown in FIG. 2 (cross-sectional view taken along the line A-A of FIG. 1). On the other hand, an insulating film 11 as an interlayer insulating film is buried on the other side of the silicon film 7, as shown in FIG. 2 (cross-sectional view taken along the line A-A of FIG. 1). As seen from FIG. 3 (cross-sectional view taken along the line B-B of FIG. 1), no insulating film 11 is buried in the silicon film 7 on the side shown in the section of FIG. 3.

A silicon film 14 is formed on the insulating film 8 via insulating films 12 and 13 functioning as an interlayer insulating film. The side of the silicon film 14 is provided with a gate insulating film 22. A silicon film 16 is formed on the silicon film 14 via an insulating film 15 as an interlayer insulating film. The side of the silicon film 16 is provided with a gate insulating film 22. A silicon film 18 is formed on the silicon film 16 via an insulating film 17 as an interlayer insulating film. The side of the silicon film 18 is provided with a gate insulating film 22. A silicon film 20 is formed on the silicon film 18 via an insulating film as an interlayer insulating film. The side of the silicon film 20 is provided with a gate insulating film 22. An insulating film 21 functioning as an insulating film is formed on the gate insulating film 22.

A silicon film 23 is buried on the silicon film 10. The silicon film 23 is provided on the sides of the gate insulating film 22, insulating films 12, 13, 15, 17, 19 and 21, and has U-shape in cross-section. The silicon film 23 is connected with the silicon film 10.

An anti-reaction film 24, a phase change film 25 and an insulating film 26 as an interlayer insulating film are stacked on the silicon film 23. A heat sink film 27 is buried on the insulating film 26. A silicon film 28 is formed on the insulating film 21. The silicon film 28 is connected with the silicon film 23 and the phase change film 25. The silicon film 28 is isolated from the heat sink film 27 via an insulating film 30 functioning as an interlayer insulating film. An insulating film 29 as an interlayer insulating film is formed on the silicon film 28. Illustration and explanation are omitted with respect to interconnect layer, interlayer insulating film and surface protective film, which are formed on the insulating film 29.

For example, an amorphous silicon film having an N-type impurity is used as the silicon films 7, 10, 14, 16, 18, 20, 23 and 28. A GST (GeSbTe chalcogenide) film is used as the phase change film 25. The anti-reaction film 24 prevents the silicon films 10 and 23 from reacting with the phase change film 25 in a process of manufacturing the phase change memory 40, that is, a heat treatment process. In addition, the anti-reaction film 24 electrically connects the transistor forming the memory cell and the phase change film 25. For example, a very thin silicon nitride film (SiN) is used as the anti-reaction film 24. When the memory cell is operated, current from several tens of μA to several hundred of μA is carried between the transistor and the phase change film 25 via the anti-reaction film 24. The heat sink film 27 dissipates heat generated in the phase change film 25 when the memory cell is operated. For example, a titanium nitride (TiN) film is used as the heat sink film 27.

As depicted in FIG. 4 to FIG. 6, a vertical type selecting transistor TR5 is formed on the interconnect layer 4. In the vertical type transistor TR5, a gate electrode is formed of the silicon film 7, a gate insulating film is formed of the gate insulating film 9, and a channel layer is formed of the silicon film 10. In this case, the vertical type transistor means that a channel portion of the transistor extends with respect to the semiconductor substrate 1 in the thickness direction of the semiconductor substrate 1. In the transistor TR5, one of the source and drain is connected to the source line SL, and the other of the source and drain is connected to a first-stage memory cell, and the gate is connected to the word line WL. The source line SL is controlled by a driver transistor DTRSL1. The word line WL is controlled by a driver transistor DTRWL1. Transistors TR1 to TR4 are vertical type memory cell transistors.

A first-stage memory cell is composed of a vertical type memory cell transistor TR1 and a phase change element SR1. The transistor TR1 comprises a gate electrode formed of the silicon film 14, a gate insulating film formed of the gate insulating film 22 and a channel formed of the silicon film 23. The phase change element SR1 comprises the phase change film 24. One of the source and drain of the transistor TR1 is connected to one terminal of the phase change element SR1 and said other of the source and drain of the vertical type selecting transistor TR5. The other of the source and drain of the transistor TR1 is connected to the other terminal of the phase change element SR1. The gate of the transistor TR1 is connected to a gate G1.

A second-stage memory cell is composed of a vertical type memory cell transistor TR2 and a phase change element SR2. The transistor TR2 comprises a gate electrode formed of the silicon film 16, a gate insulating film formed of the gate insulating film 22 and a channel formed of the silicon film 23. The phase change element SR1 comprises the phase change film 24. One of the source and drain of the transistor TR2 is connected to one terminal of the phase change element SR2 and said other of the source and drain of the transistor TR1. The other of the source and drain of the transistor TR2 is connected to the other terminal of the phase change element SR2. The gate of the transistor TR2 is connected to a gate G2.

A third-stage memory cell is composed of a vertical type memory cell transistor TR3 and a phase change element SR3. The transistor TR3 comprises a gate electrode formed of the silicon film 18, a gate insulating film formed of the gate insulating film 22 and a channel formed of the silicon film 23. The phase change element SR3 comprises the phase change film 24. One of the source and drain of the transistor TR3 is connected to one terminal of the phase change element SR3 and said other of the source and drain of the transistor TR2. The other of the source and drain of the transistor TR3 is connected to the other terminal of the phase change element SR3. The gate of the transistor TR3 is connected to a gate G3.

A fourth-stage memory cell is composed of a vertical type memory cell transistor TR4 and a phase change element SR4. The transistor TR4 comprises a gate electrode formed of the silicon film 20, a gate insulating film formed of the gate insulating film 22 and a channel formed of the silicon film 23. The phase change element SR4 comprises the phase change film 24. One of the source and drain of the transistor TR4 is connected to one terminal of the phase change element SR4 and said other of the source and drain of the transistor TR3. The other of the source and drain of the transistor TR4 is connected to the other terminal of the phase change element SR4 and the bit line BL. The gate of the transistor TR4 is connected to a gate G4.

The gate G1 is controlled by a driver transistor DTRG1, the gate G2 is controlled by a driver transistor DTRG2, the gate G3 is controlled by a driver transistor DTRG3, and the gate G4 is controlled by a driver transistor DTRG4. The bit line BL is controlled by a driver transistor DTRG1. Transistors TR1 to TR5 are a D type (normally-on type) Nch MISFET (Metal Insulator semiconductor Field Effect transistor) of the vertical type transistor. The MISFET is called as a MIS transistor.

A memory cell array formed of the four stacked memory cells and the vertical type selecting transistor TR5 form one unit cell. A plurality of unit cells of this structure is arrayed on the upper surface of the semiconductor substrate 1.

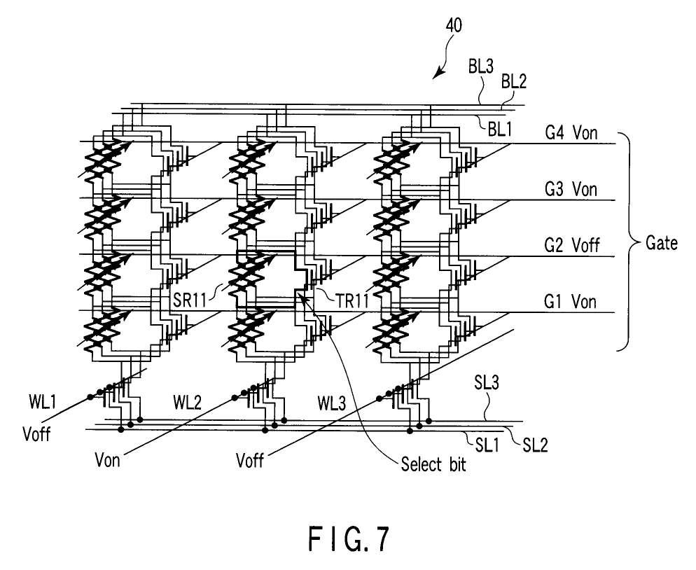

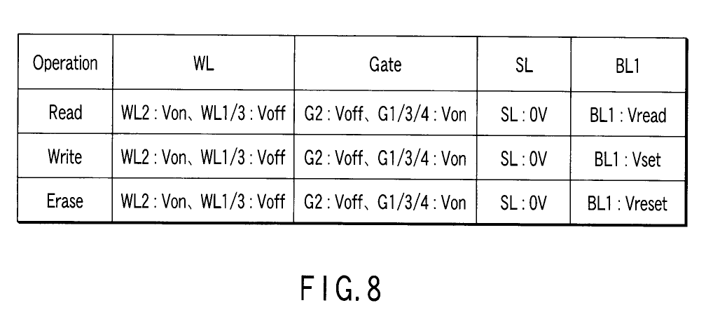

The operation of the phase change memory will be hereinafter described with reference to FIG. 7 and FIG. 8. FIG. 7 is an equivalent circuit diagram to explain the operation of the phase change memory. FIG. 8 is a table to explain the operation of the phase change memory.

As shown in FIG. 7, unit cells of the above mentioned structure are arrayed in parallel to each other in the memory cell portion of the phase change memory 40. The unit cells are provided between the bit line BL1 and the source line SL1. Each of the unit cells is composed of a memory cell array having four stacked memory cells and a vertical type selecting transistor connected to the memory cell array. The gates of the vertical type selecting transistors arrayed in parallel to each other are connected with the word lines. The gates of the cell transistors of the first-stage memory cells are connected to the gate G1. The gates of the cell transistors of the second-stage memory cells are connected to the gate G2. The gates of the cell transistors of the third-stage memory cells are connected to the gate G3. The gates of the cell transistors of the fourth-stage memory cells are connected to the gate G4. In short, the gates of memory cell transistors in each layer are operated with the same gate potential.

As shown in, for example, FIG. 8, a memory cell comprising a cell transistor TR11 and a phase change element SR11 is selected by the source line SL1, the bit line BL1, the word line WL2 and the gate G2, as a select bit. In this case, when a Read operation is to be set, the word line WL2 is set to a threshold voltage of the transistor, for example, +1 V, that is, Von. Other word lines are set to ground potential 0 V, that is, Voff. The gate G2 is set to Voff, and other gates are set to Von. The source line SL is set to 0 V, and the bit line B11 is set to a read voltage Vread. In this way, the magnitude of current carrying the bit line BL1 is read, and thereby, bit information is read from the selected memory cell.

When a Set operation (write operation) is to be set, the word line WL2 is set to the threshold voltage of transistor, for example, +1 V, that is, Von. Other word lines are set to ground potential 0 V, that is, Voff. The gate G2 is set to Voff, and other gates are set to Von. The source line SL is set to 0 V, and the bit line is set to a set voltage Vset. In this way, a relatively small current flows through the phase change element SR11 to poly-crystallize the phase change film (a state of low resistance “1”).

When a Reset operation (erase operation) is to be set, the word line WL2 is set to the threshold voltage of transistor, for example, +1 V, that is, Von. Other word lines are set to ground potential 0 V, that is, Voff. The gate G2 is set to Voff, and other gates are set to Von. The source line SL is set to 0 V, and the bit line is set to a reset voltage Vreset. In this way, a relatively large current flows through the phase change element SR11 to make amorphous the phase change film (a state of high resistance “0”).

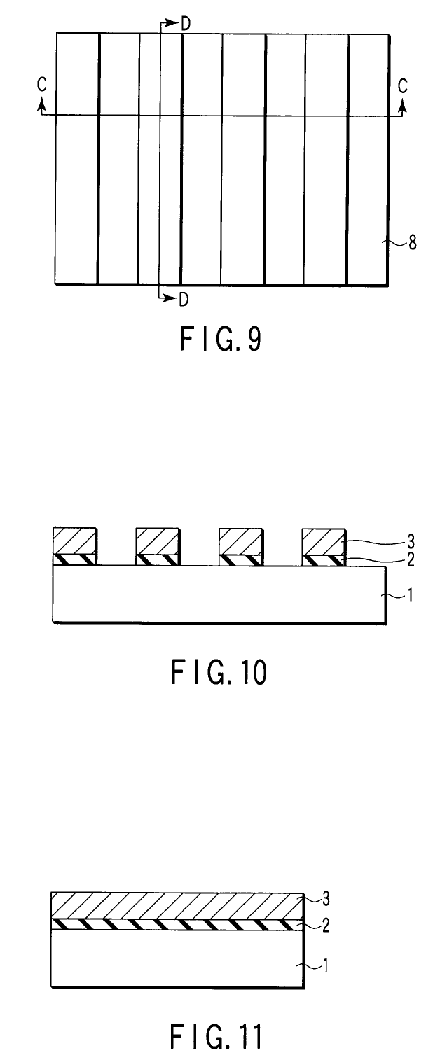

A method of manufacturing the phase change memory will be hereinafter described with reference to FIG. 9 to FIG. 47. FIG. 9 to FIG. 47 show views used for explaining the steps of the manufacturing method of the phase change memory.

As shown in FIG. 9 to FIG. 11, a plurality of stacked film structures each comprised of an insulating film 2 and an interconnect layer 3 are selectively formed on a semiconductor substrate. For example, a W (tungsten) film is used as the interconnect layer 3. Instead, N⁺ polysilicon film (doped with N-type impurity at high concentration) may be used. The interconnect layer 3 is used as the source line SL.

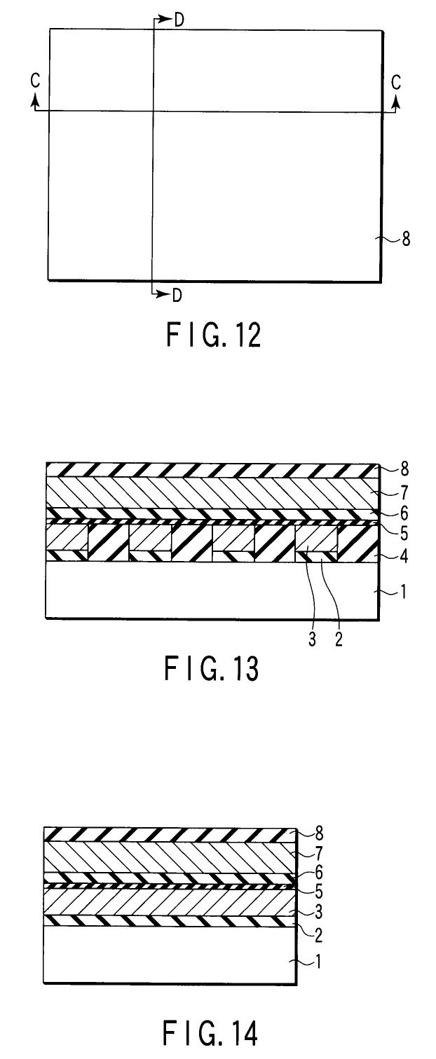

As illustrated in FIG. 12 to FIG. 14, an insulating film is buried between adjacent stacked film structures each comprised of the insulating film 2 and the interconnect layer 3. In order to bury the insulating film 4, the insulating film 4 is deposited more than the thickness of the insulating film 2 and interconnect layer 3. Then, the insulating film 4 is polished by using a CMP (Chemical Mechanical Polishing) process, until the surface of the interconnect layer 3 is exposed. Insulating films 5, 6, silicon film 7 made of amorphous silicon doped with N-type impurity and insulating film 8 are stacked on the interconnect layer 3 and the insulating film 4. A silicon nitride (SiN) film, for example, is used as the insulating film 5. Amorphous silicon is used as the silicon film 7 in this embodiment, however, a polysilicon film having N-type impurity may be used, instead.

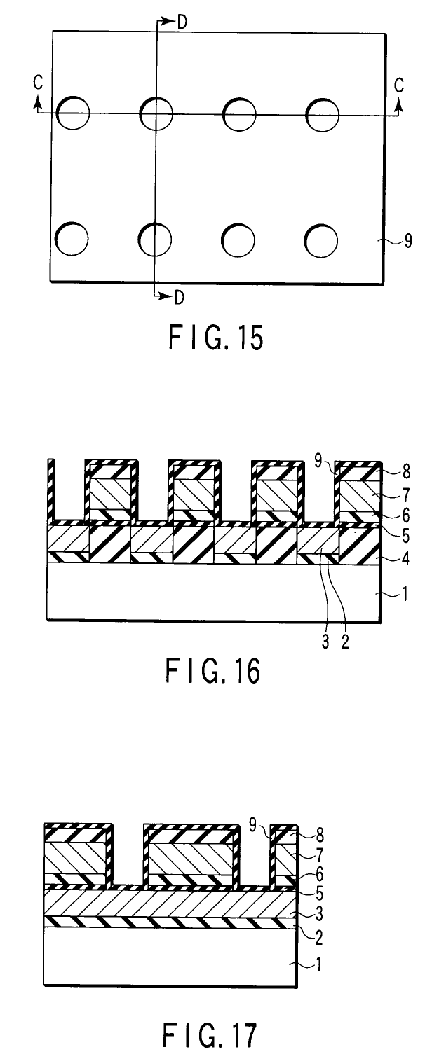

As depicted in FIG. 15 to FIG. 17, insulating film 8, silicon film 7, insulating films 6 and 5 formed on the interconnect layer 3 are selectively etched to form a first circle opening for formation of a vertical type selecting transistor in which the surface of the interconnect layer 3 is exposed. The exposed side of the silicon film 7 is formed with a gate insulating film. In addition, the exposed interconnect layer 3 and the exposed insulating films 6 and 8 are formed with the gate insulating film 9. In this embodiment, the first opening is formed into a circle shape, however, it may be formed into a polygon such as square.

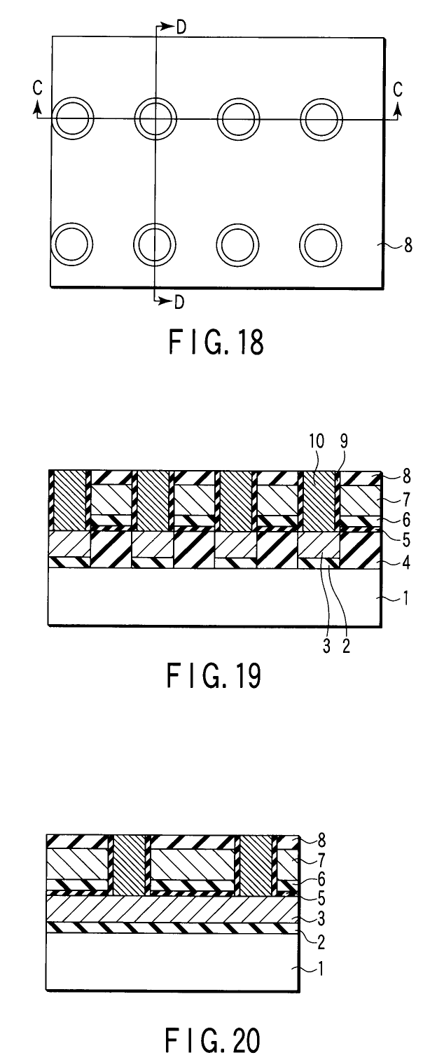

As seen from FIG. 18 to FIG. 20, the interconnect layer 3 and the gate insulating film on the insulating film 8 are selectively etched to expose each upper surface of the interconnect layer 3 and the insulating film 8. For example, RIE (Reactive Ion Etching) is used as the selective etching process. The first opening is filled with a silicon film 10 made of amorphous silicon doped with N-type impurity. For example, the silicon film 10 is filled in the following manner. Specifically, the silicon film 10 is deposited more than the total thickness of insulating films 5, 6, silicon film 7 and insulating film 8. Then, the silicon film 10 is polished until the surface of the insulating film 8 is exposed by using CMP (chemical Mechanical Polishing). In this embodiment, the amorphous silicon film is used as the silicon film 10. However, a polysilicon film having N-type impurity may be used, instead.

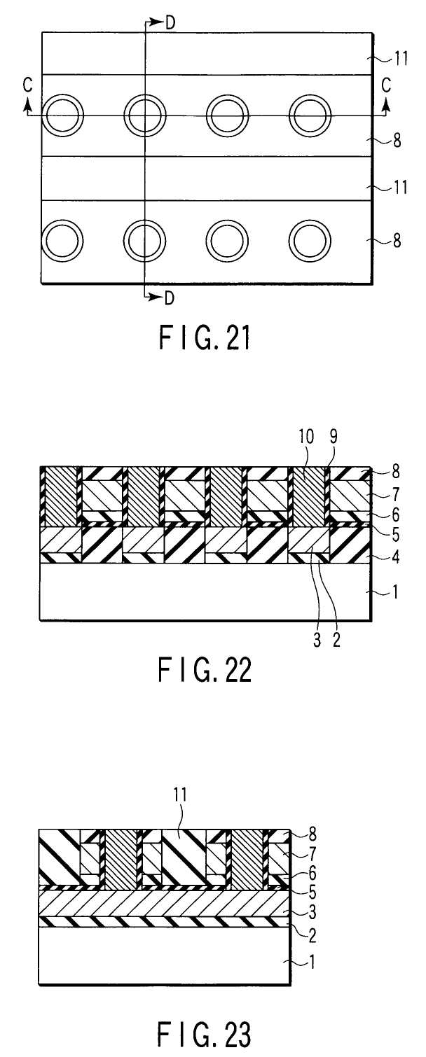

In a section shown in FIGS. 21 and 22, and FIG. 23 (taken along the line D-D of FIG. 9, that is, shown in an extending direction of the interconnect layer used as the source line SL), insulating films 8, 6 and silicon film 7 selectively etched. In this way, a second opening is formed so that the upper portion of the insulating film 5 is exposed. With the second opening being formed, word lines WL formed of silicon film 7 are configured. The second opening is filled with an insulating film 11.

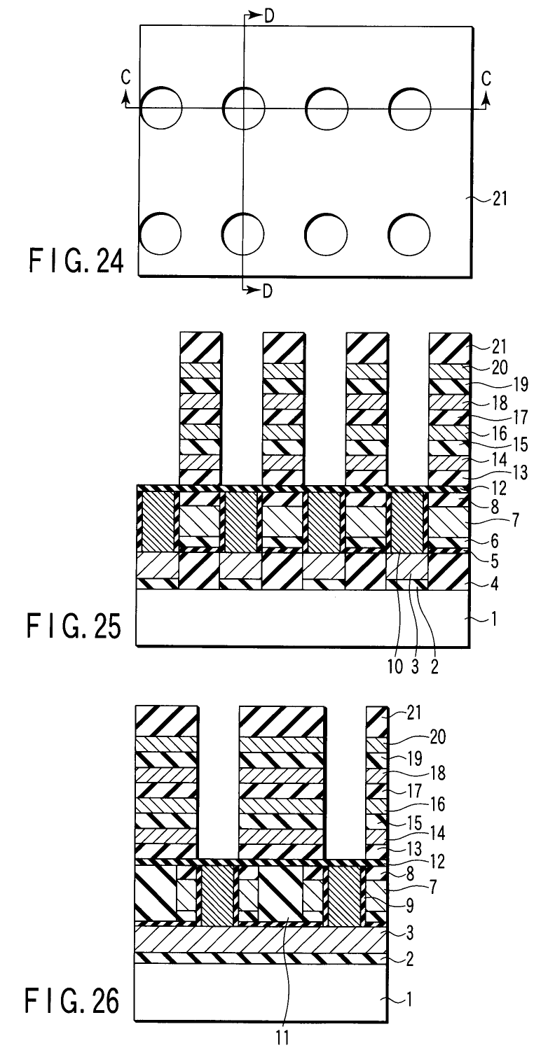

As shown in FIG. 24 to FIG. 26, the following films are successively stacked on the insulating film 8, silicon film 7 and the insulating film 6. The above mentioned films include insulating film 12, insulating film 13, silicon film 14, insulating film 15, silicon film 16, insulating film 17, silicon film 18, insulating film 19, silicon film 20 and insulating film 21. For example, a silicon nitride (SiN) film is used as the insulating film 12. An amorphous silicon film doped with N-type impurity at high concentration is used as the silicon films 14, 16, 18 and 20. A polysilicon film doped with N-type impurity at high concentration may be used, instead. The insulating film 21, silicon film 20, insulating film 19, silicon film 18, insulating film 17, silicon film 16, insulating film 15, silicon film 14 and insulating film 13, which are on the silicon film 10, are etched away. In this way, a third opening is formed so that the upper surface of the insulating film 12 is exposed. The shape of the third opening determines a shape of the transistor and the phase change element forming the memory cell. In other word, the shape of the transistor and the phase change element is determined according to one-time photolithography process. The details will be explained after the following step.

In this embodiment, the third opening is formed into the same shape (circle shape) as the first opening. However, a polygon such as square may be formed, instead. Preferably, the third opening is formed into the same shape as the first opening.

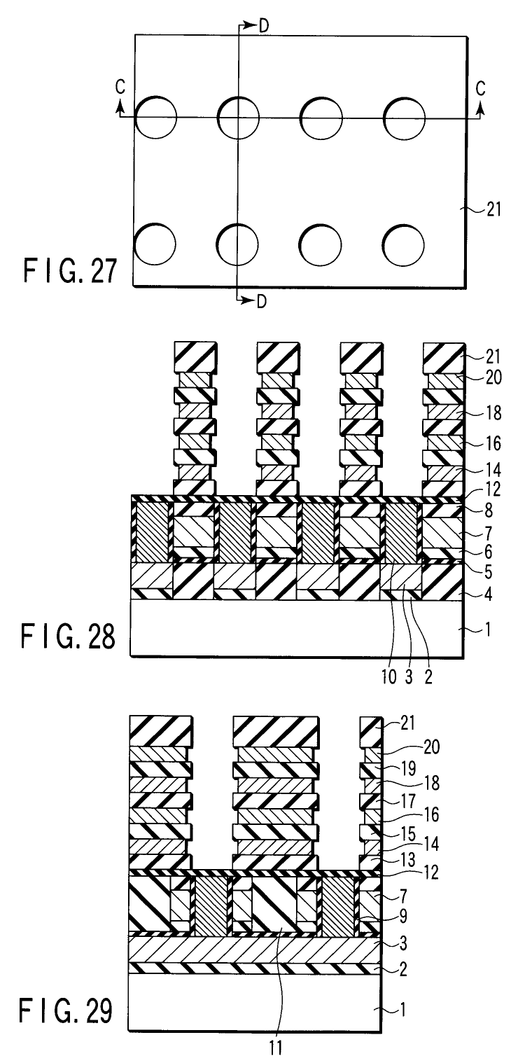

As illustrated in FIG. 27 to FIG. 29, each side of silicon films 14, 16, 18 and 20 is etched by using isotropic etching such as CDE (Chemical Dry Etching) to reduce the thickness of these films. In this case, according to the CED, the following condition (etching selectivity) is set. Specifically, an etching rate of the silicon film becomes larger than that of the insulating film 12 such as SiN film.

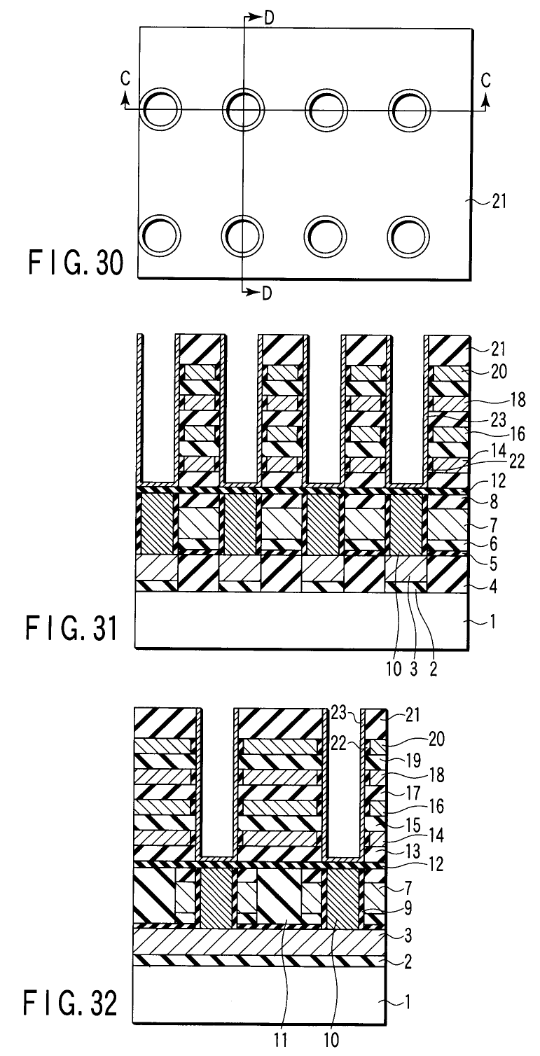

As depicted in FIG. 30 to FIG. 32, each side of silicon films 14, 16, 18 and 20 is formed with a gate insulating film 22. A SiNxOy film made by thermally nitrifying a silicon oxide film, a stacked film of silicon nitride film (Si₃N₄)/silicon oxide film or high dielectric film (high-K gate insulating film) is used as the gate insulating film 22. In stead, a silicon oxide film made by thermally oxidizing a silicon film may be used. In this case, a MOS transistor is given as the memory cell transistor. The gate insulating film is formed, and thereafter, the third opening is formed with a silicon film 23. Then, the silicon film 23 on the insulating film 21, the insulating film 12 on the silicon film 10 and the silicon film 23 are etched. For example, RIE (Reactive Ion Etching) is used as the foregoing etching. An amorphous silicon film doped with N-type impurity is used as the silicon film 23. However, a polysilicon film doped with N-type impurity may be used, instead. The silicon film 23 protects the gate insulating film 22 from damages occurred after this process.

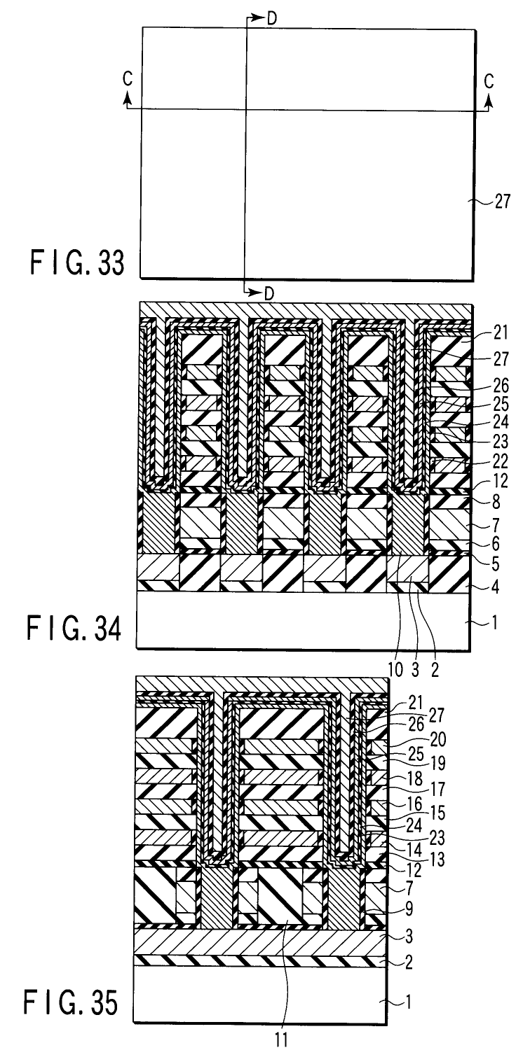

As seen from FIG. 33 to FIG. 35, silicon film 23, anti-reaction film 24, phase change film 25, insulating film 26 and heat sink film 27 are successively stacked. The silicon film 23 is connected to the silicon film 10. For example, a silicon nitride film (SiN) having a thickness of about 1 nm is used as the anti-reaction film 24. GST (GeSbTe chalcogenide) is used as the phase change film 25, however, AsSbTe, SeSbTe or AsSbTe, and further, SeSbTe added with additives (O (oxygen), N (nitrogen) or Si (silicon) may be used, instead. A titanium nitride (TiN) film is used as the radiator film 27, however, metal such as tungsten (W) and aluminum (AL) may be used, instead.

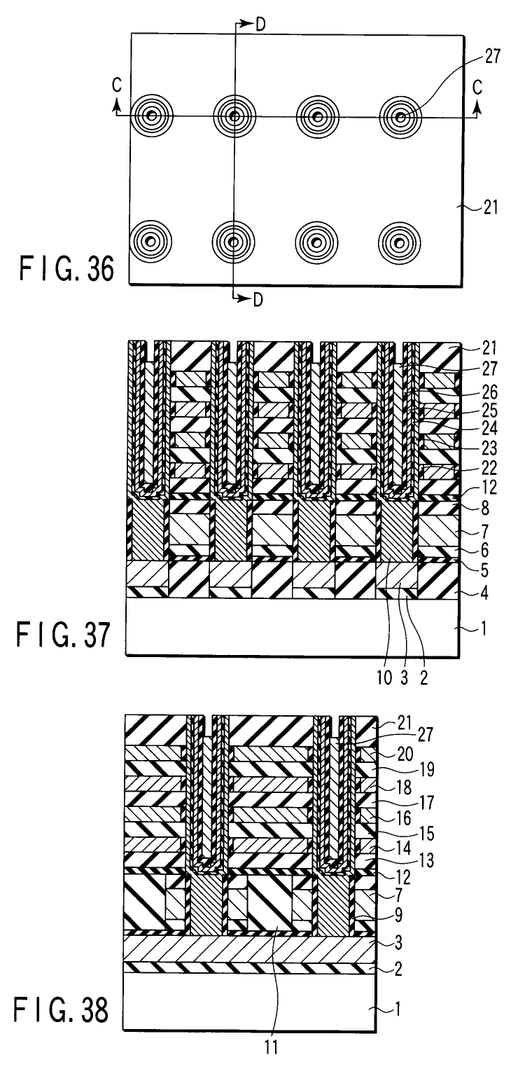

As shown in FIG. 36 to FIG. 38, the interconnect layer 21 is polished until the surface is exposed by using CMP (Chemical Mechanical Polishing) to planarize the surface of the phase change memory 40. After planarization is completed, the upper portion of the radiator film 27 is etched back.

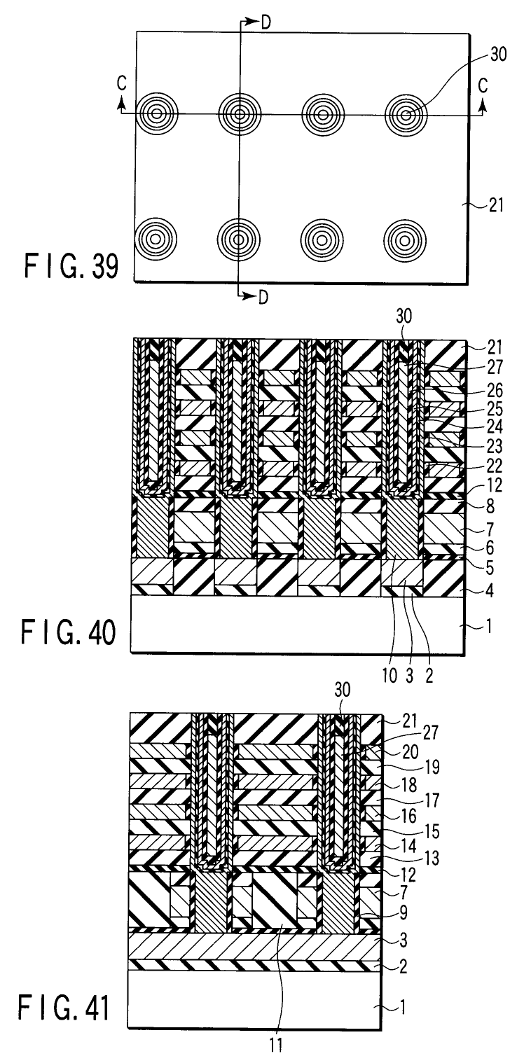

As illustrated in FIG. 39 to FIG. 41, the surface of the phase change memory 40 is formed with an insulating film 30. The insulating film is polished until the surface of the interconnect layer 21 is exposed by using CMP to planarize the surface of the phase change memory 40. In this way, the insulating film 30 is left on the upper surface of the radiator film 27 with a predetermined thickness.

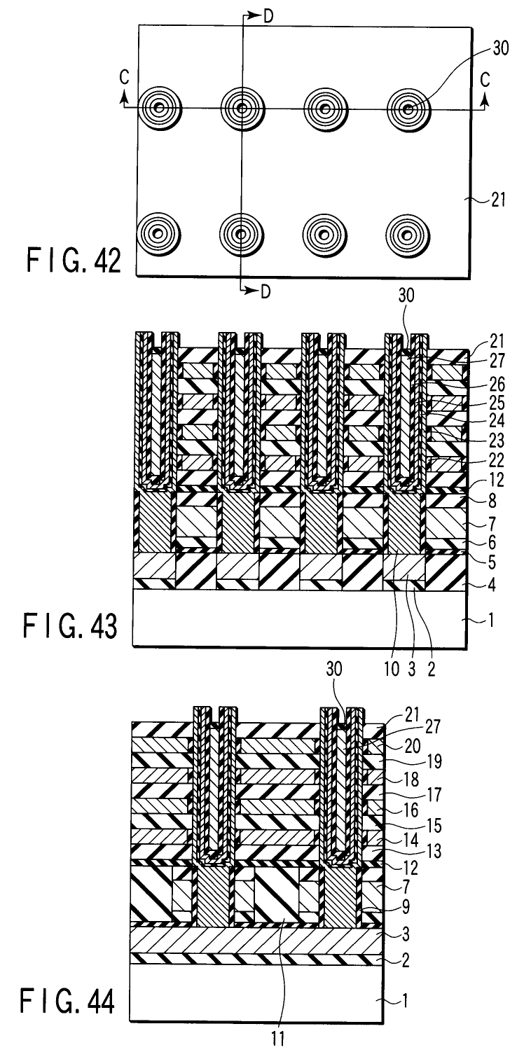

As depicted in FIG. 42 to FIG. 44 the insulating film on the surface of the phase change memory 40 is etched back to expose each upper portion of the silicon film 23 and the phase change film 25. According to the etch-back, the insulating film 30 is etched back, however, it is left on the upper surface of the radiator film 27 with a predetermined thickness.

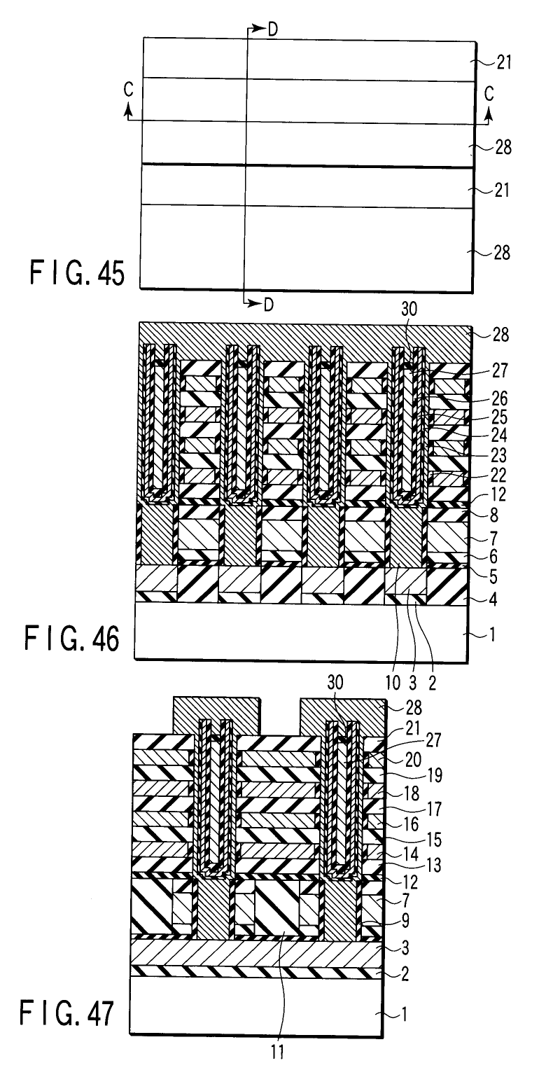

As seen from FIG. 45 to FIG. 47, the surface of the phase change memory 40 is formed with a silicon film 28. The silicon film 28 except portions functioning as the bit line BL is removed by using etching. An insulating film 29 is formed, and thereafter, interlayer insulating films and interconnect layers are formed by using a known technique, and thus, the phase change memory (PRAM) 40 is completed.

As described above, in the semiconductor memory device and the manufacturing method according to this embodiment, a unit cell composed of the vertical type selecting transistor and the memory cell array is formed on the semiconductor substrate 1. The memory cell array comprises stacked four-stage memory cells composed of the phase change element and the cell transistor. A plurality of source lines SL is provided in parallel on the side of the semiconductor substrate. A plurality of word lines WL is formed in parallel to each other above the source line SL and a plurality of bit lines BL is formed in parallel to each other above the memory cell. The word lines WL and the bit lines BL are provided perpendicularly to the source lines SL. The gates Gate of the cell transistors are isolated via the insulating films, and extended in a direction reverse to the bit lines BL. The source lines SL, word lines WL, bit lines BL and gates Gate are connected to the corresponding interconnect layers by way of corresponding vias. In the vertical type selecting transistor TR5 formed on the interconnect layer 4, one of the source and drain is connected to the source line SL, the other of the source and drain is connected to the first-stage memory cell, and the gate is connected the word line WL. In the first-stage memory cell transistor TR1, one of source and drain is connected to the other of source and drain of the selecting transistor TR5 and one terminal of the phase change element SR1 of the first-stage memory cell. The other of source and drain is connected to the other terminal of the phase change element SR1, and the gate is connected to the gate G1. In the second-stage memory cell transistor TR2, one of the source and drain is connected to the other of source and drain of the memory cell transistor TR1 and between the phase change element SR1 of the first-stage memory cell and the phase change element SR2 of the second-stage memory cell. The other of the source and drain is connected between the phase change element SR2 of the second-stage memory cell and the phase change element SR3 of the third-stage memory cell. The gate is connected to the gate G2. In the third-stage memory cell transistor TR3, one of the source and drain is connected to the other of the source and drain of the memory cell transistor TR2 and between the phase change element SR2 of the second-stage memory cell and the phase change element SR3 of the third-stage memory cell. The other of the source and drain is connected between the phase change element SR3 of the third-stage memory cell and the phase change element SR4 of the fourth-stage memory cell. The gate is connected to the gate G3. In the fourth-stage memory cell transistor TR4, one of the source and drain is connected to the other of the source and drain of the memory cell transistor TR3 and between the phase change element SR3 of the third-stage memory cell and the phase change element SR4 of the fourth-stage memory cell. The other of the source and drain is connected to the bit line BL and the other terminal of the phase change element SR4 of the fourth-stage memory cell. The gate is connected to the gate G4. Each shape of the vertical type selecting transistor TR5, the four-stage structure memory cell transistor and the phase change element is determined using one-time photolithography process. Gates G1 to G4 are formed into a plate shape on the semiconductor substrate 1 via the insulating film.

Therefore, the word lines WL and the bit lines BL are independently provided every layer. The shape of the vertical type selecting transistor TR5, the four-stage structure memory cell transistors and the phase change element is determined via one-time photolithography process regardless of the number of stacked memory cells. This serves to largely reduce a phase change memory chip including a memory cell area while preventing an increase of the photolithography process as compared with the conventional case. The vertical selecting transistor and the memory cell transistor are not provided with source and drain layers of high-concentration. Thus, the transistor is given as a D type (normally on type). Therefore, the number of manufacturing processes is largely reduced.

In the first embodiment, stacked four-stage memory cells of the phase change memory are formed on the semiconductor substrate. The stage number to be provided is not limited to four stages. A plurality of stacked stages of memory cells other than four stages may also be formed. An amorphous silicon film is used as the gate electrode film of the transistor forming the memory cell and the silicon film 28. However, a metal silicide film may be used, instead. Moreover, thin insulating film and thin heat sink film may be periodically and repeatedly in place of the radiator film. The thin heat sink film prevents and seals dissipation of radiation of generated heat.

### Second Embodiment

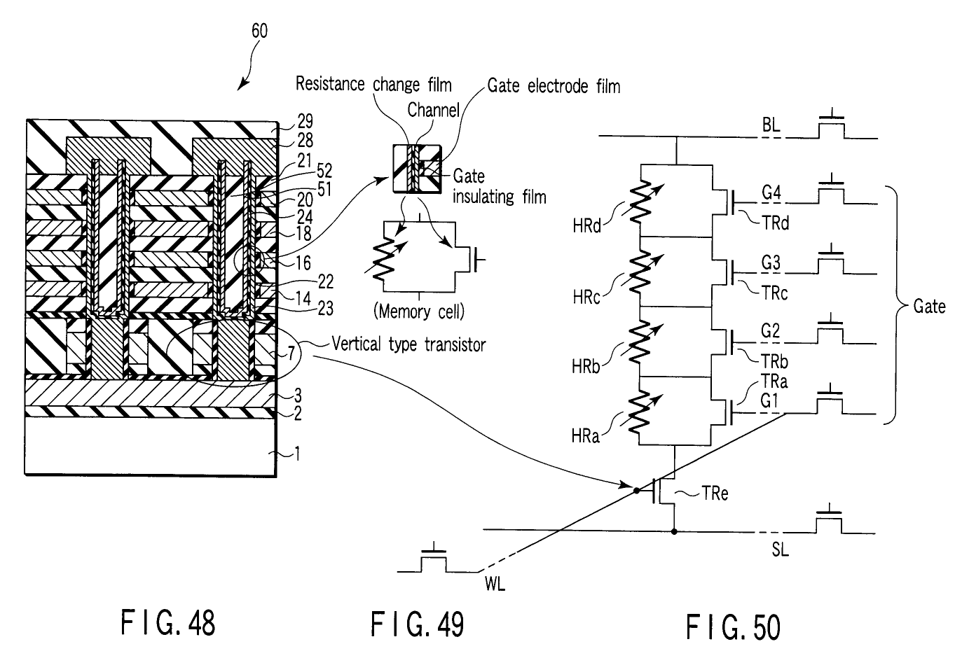

A semiconductor memory device and a method of manufacturing the same according to a second embodiment of the present invention will be hereinafter described with reference to the accompanying drawings. FIG. 48 is a cross-sectional view of a memory cell portion of a semiconductor memory device according to a second embodiment of the present invention. FIG. 49 is a cross-sectional view showing one memory cell of the semiconductor memory device shown in FIG. 48. FIG. 50 is a view showing an equivalent circuit diagram of the semiconductor memory device shown in FIG. 48. In the second embodiment, the memory cell of the PRAM is stacked on a semiconductor substrate to form a three-dimensional memory cell.

In the following description, the same reference numbers are used to designate portions identical to the first embodiment, and different portions only will be described.

As shown in FIG. 48 to FIG. 50, in the memory cell portion of the RRAM (resistive change random access memory), a unit cell composed of a vertical selecting transistor and a memory cell array is formed on a semiconductor substrate 1. The memory cell array is composed of stacked four-stage memory cells each comprising a resistance change element and a vertical type memory cell transistor. Illustration and description of a lead portion and an input/output portion of the memory cell of the RRAM 60 are omitted.

In a vertical type selecting transistor TRe formed on an interconnect layer, a gate electrode is formed of a silicon film 7, a gate insulating film is formed of a gate insulating film 9, a channel layer is formed of a silicon film 10. In the selecting transistor TRe, one of the source and drain is connected to a source line SL, the other thereof is connected to a firs-stage memory cell, and a gate is connected to a word line WL.

A first-stage memory cell is composed of a vertical type memory cell transistor TRa and a resistance change element HRa. The memory cell transistor TRa comprises a gate electrode formed of the silicon film 14, a gate insulating film formed of the gate insulating film 22 and a channel formed of the silicon film 23. The resistance change element HRa comprises the resistance change film 51. One of the source and drain of the memory cell transistor TRa is connected to one terminal of the resistance change element HRa and said other of the source and drain of the selecting transistor TRe. The other of the source and drain of the memory cell transistor TRa is connected to the other terminal of the resistance change element HRa. The gate of the memory cell transistor TRa is connected to a gate G1.

A second-stage memory cell is composed of a vertical type memory cell transistor TRb and a resistance change element HRb. The memory cell transistor TRb comprises a gate electrode formed of the silicon film 16, a gate insulating film formed of the gate insulating film 22 and a channel formed of the silicon film 23. The resistance change element HRa comprises the resistance change film 51. One of the source and drain of the memory cell transistor TRb is connected to one terminal of the resistance change element HRb and said other of the source and drain of the memory cell transistor TRa. The other of the source and drain of the memory cell transistor TRb is connected to the other terminal of the resistance change element HRb. The gate of the memory cell transistor TRb is connected to a gate G2.

A third-stage memory cell is composed of a vertical type memory cell transistor TRc and a resistance change element HRc. The memory cell transistor TRc comprises a gate electrode formed of the silicon film 18, a gate insulating film formed of the gate insulating film 22 and a channel formed of the silicon film 23. The resistance change element HRc comprises the resistance change film 51. One of the source and drain of the memory cell transistor TRc is connected to one terminal of the resistance change element HRc and said other of the source and drain of the memory cell transistor TRb. The other of the source and drain of the memory cell transistor TRc is connected to the other terminal of the resistance change element HRc. The gate of the memory cell transistor TRc is connected to a gate G3.

A fourth-stage memory cell is composed of a vertical type memory cell transistor TRd and a resistance change element HRd. The memory cell transistor TRd comprises a gate electrode formed of the silicon film 20, a gate insulating film formed of the gate insulating film 22 and a channel formed of the silicon film 23. The resistance change element HRd comprises the resistance change film 51. One of the source and drain of the memory cell transistor TRd is connected to one terminal of the resistance change element HRd and said other of the source and drain of the memory cell transistor TRc. The other of the source and drain of the memory cell transistor TRd is connected to the other terminal of the resistance change element HRd and the bit line BL. The gate of the memory cell transistor TRd is connected to a gate G4.

A transition metal oxide film, for example, is used as a resistance change film 51. Transistors TRa to TRe are a D type (normally-on type) Nch MISFET (Metal Insulator Semiconductor Field Effect Transistor) of the vertical transistor. The memory cell array composed of stacked four-stage memory cells and the vertical type selecting transistor TRe form one unit cell. A plurality of the unit cells is arrayed on the upper surface of the semiconductor substrate 1.

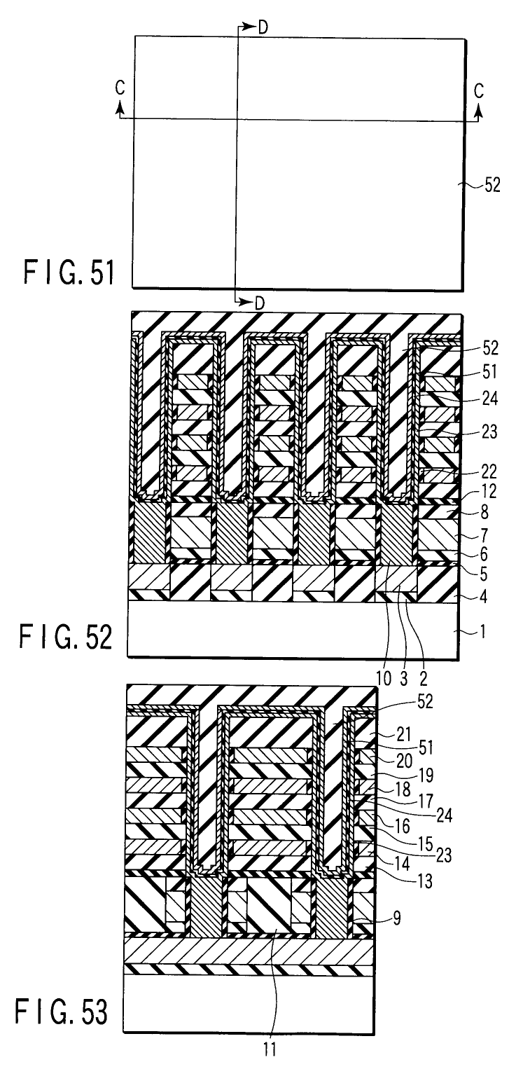

The method of manufacturing the RRAM shown in FIG. 48 to FIG. 50 will be hereinafter described with reference to FIG. 51 to FIG. 62. FIG. 51 to FIG. 62 are views used for explaining the steps of manufacturing the RRAM shown in FIG. 48. The same process as the first embodiment is carried out until the silicon film 23 (FIG. 30 to FIG. 32) is formed, and therefore, the explanation is omitted.

As shown in FIG. 51 to FIG. 53, silicon film 23, anti-reaction film 24, resistance change film 51 and insulating film 52 are successively stacked. In this embodiment, a transition metal oxide film is used as the resistance change film 51. However, a perovskite-type oxide film doped with transition metal may be used, instead. This transition metal oxide film is a metal oxide including nickel oxide, niobate oxide, copper oxide, hafnium oxide or zirconium oxide.

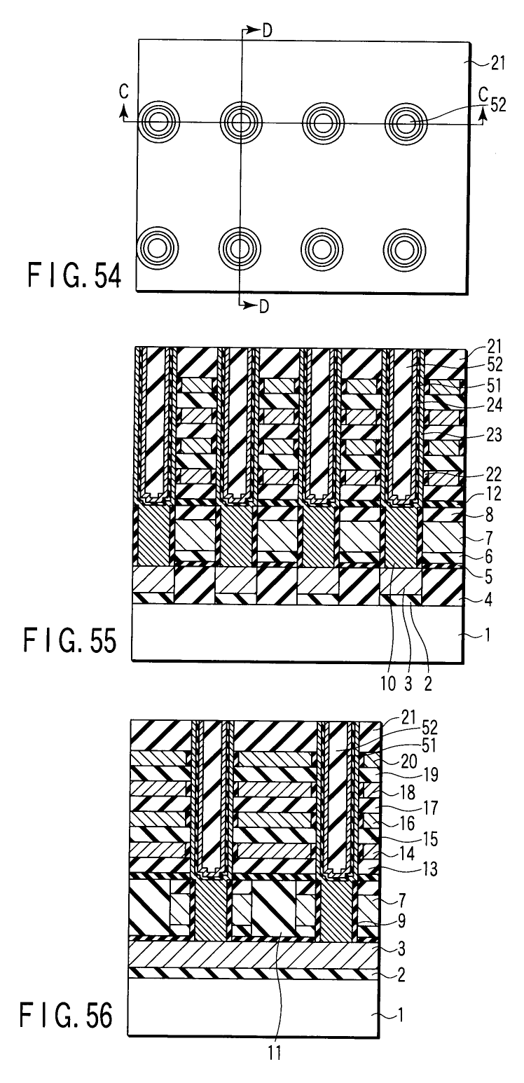

As illustrated in FIG. 54 to FIG. 56, the interconnect layer 21 is polished until the surface is exposed by using CMP (Chemical Mechanical Polishing) to planarize the surface of the RRAM 60.

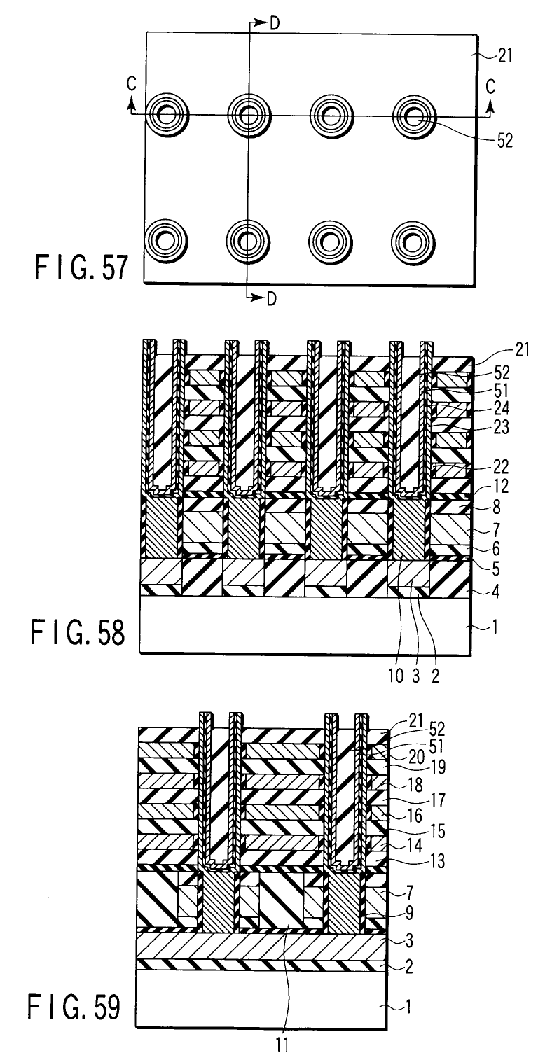

As depicted in FIG. 57 to FIG. 59, insulating films 21 and 52 on the surface of the RRAM 60 are further etched back to expose each surface of the silicon film 23 and the resistance change film 51. In the etch-back, etch-back is carried out so that the insulating film 21 on the silicon film 20 is left with a predetermined thickness.

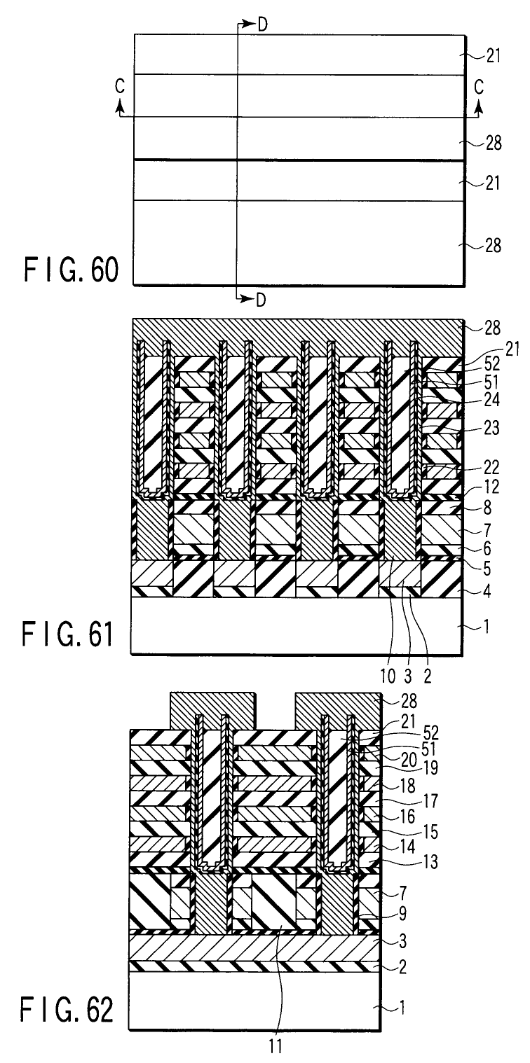

As seen from FIG. 60 to FIG. 62, the surface of the RRAM 60 is formed with a silicon film 28. The silicon film 28 except portion functioning as the bit line is removed by using etching. An insulating film 29 is formed, and thereafter, interlayer insulating films and interconnect layers are formed by using a known technique, and thus, the RRAM 60 is completed.

As described above, in the semiconductor memory device and the manufacturing method according to this embodiment, a unit cell composed of the vertical type selecting transistor and the memory cell array is formed on the semiconductor substrate 1. The memory cell array comprises stacked four-stage memory cells composed of the resistance change element and the cell transistor. A plurality of source lines SL is provided in parallel on the side of the semiconductor substrate. A plurality of word lines WL is formed in parallel to each other above the source line SL and a plurality of bit lines BL is formed in parallel to each other above the memory cell. The word lines WL and the bit lines BL are provided perpendicularly to the source lines SL. The gates Gate of the cell transistors are isolated via the insulating films, and extended in a direction reverse to the bit lines BL. The source lines SL, word lines WL, bit lines BL and gates Gate are connected to the corresponding interconnect layers by way of corresponding vias. In the vertical type selecting transistor TRe formed on the interconnect layer 4, one of the source and drain is connected to the source line SL, the other of the source and drain is connected to the first-stage memory cell, and the gate is connected the word line WL. In the first-stage memory cell transistor TRa, one of source and drain is connected to the other of source and drain of the selecting transistor TRe and one terminal of the resistance change element HRa of the first-stage memory cell. The other of the source and drain is connected to the other terminal of the resistance change element HRa, and the gate is connected to the gate G1. In the second-stage memory cell transistor TRb, one of the source and drain is connected to the other of source and drain of the memory cell transistor TRa and between the resistance change element HRa of the first-stage memory cell and the resistance change element HRb of the second-stage memory cell. The other of the source and drain is connected between the resistance change element HRb of the second-stage memory cell and the resistance change element HRc of the third-stage memory cell. The gate is connected to the gate G2. In the third-stage memory cell transistor TRc, one of the source and drain is connected to the other of the source and drain of the memory cell transistor TRb and between the resistance change element HRb of the second-stage memory cell and the resistance change element HRc of the third-stage memory cell. The other of the source and drain is connected between the resistance change element HRc of the third-stage memory cell and the resistance change element HRd of the fourth-stage memory cell. The gate is connected to the gate G3. In the fourth-stage memory cell transistor TRd, one of the source and drain is connected to the other of the source and drain of the memory cell transistor TRc and between the resistance change element HRc of the third-stage memory cell and the resistance change element HRc of the fourth-stage memory cell. The other of the source and drain is connected to the bit line BL and the other terminal of the resistance change element HRd of the fourth-stage memory cell. The gate is connected to the gate G4. Each shape of the vertical type selecting transistor TRe, the four-stage structure memory cell transistor and the resistance change element is determined using one-time photolithography process. Gates G1 to G4 are formed into a plate shape on the semiconductor substrate 1 via the insulating film.

Therefore, the word lines WL and the bit lines BL are independently provided every layer. The shape of the vertical type selecting transistor TRe, the four-stage structure memory cell transistors and the phase change element is determined via one-time photolithography process regardless of the number of stacked memory cells. This serves to largely reduce a phase change memory chip including a memory cell area while preventing an increase of the photolithography process as compared with the conventional case. The vertical type selecting transistor and the memory cell transistor are not provided with source and drain layers of high-concentration. Thus, the transistor is given as a D type (normally on type). Therefore, the number of manufacturing processes is largely reduced.

In the second embodiment, stacked four-stage memory cells of the resistance change memory are formed on the semiconductor substrate. The stage number to be provided is not limited to four stages. A plurality of stacked stages of memory cells other than four stages may also be formed.

The present invention is not limited to the foregoing embodiments. Various changes may be made in a range without departing from the subject matter of the present invention.

For example, a Nch MISFET is used as the transistor forming the memory cell in the second embodiment. However, a Pch MISFET may be used. In such a case, a P-type amorphous silicon film or P-type polysilicon film is preferably used as the silicon film forming the channel. A silicon nitride (SiN) film is used as the anti-reaction film in this embodiment. However, a thin silicon oxide film may be used. In such a case, it is difficult to carry relatively large current without causing breakdown between the phase change film or the resistance change film and the transistor. Preferably, the thin silicon oxide film is broken down by carrying the current to operate the memory.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a first memory cell array formed on a semiconductor substrate and composed of a plurality of memory cells stacked in layers each having a characteristic change element and a vertical type memory cell transistor connected in parallel to each other;
a plurality of second memory cell arrays formed on the semiconductor substrate and having the same structure as the first memory cell array, and arranged in an X direction with respect to the first memory cell array; and
a plurality of third memory cell arrays formed on the semiconductor substrate and having the same structure as the first memory cell array, and arranged in a Y direction with respect to the first memory cell array, wherein
a gate voltage is applied to gates of the vertical type memory cell transistors of the first to third memory cell arrays in a same layer.

2. The semiconductor memory device according to claim 1, wherein the characteristic change element comprises a phase change film.

3. The semiconductor memory device according to claim 2, wherein the phase change film is made of GST, AsSbTe or SeSbTe.

4. The semiconductor memory device according to claim 1, wherein the characteristic change element comprises a resistance change film.

5. The semiconductor memory device according to claim 4, wherein the resistance change film is transition metal oxide film including nickel oxide, niobate oxide, copper oxide, hafnium oxide or zirconium oxide, or a perovskite-type oxide film doped with transition metal.

6. The semiconductor memory device according to claim 1, wherein the vertical type memory cell transistor comprises a normally-on type MOS transistor or normally-on type MIS transistor.

7. The semiconductor memory device according to claim 1, wherein the first, second and third memory cell arrays are formed on first, second and third vertical select transistors formed on the semiconductor substrate, respectively, and connected to the first, second and third vertical select transistors, respectively, to form first, second and third unit cells, respectively.

8. The semiconductor memory device according to claim 7, wherein sources or drains of the vertical type select transistors of the first and second unit cells are connected to a same source line, and memory cells in uppermost layers of the first and second unit cells are connected to a same bit line, and gates of the vertical type select transistors of the first and third unit cells are connected to a same word line.

9. A semiconductor memory semiconductor memory device comprising:
a memory cell array including:
a vertical type select transistor formed on a semiconductor substrate, and having one of source and drain connected to a source line and having a gate connected to a word line; and
a plurality of memory cells stacked in layers on the vertical type select transistor, and interposed between a bit line and the other of source and drain of the vertical type select transistor, each of the memory cells having a characteristic change element and a vertical type memory cell transistor connected in parallel to each other, wherein
a gate of the vertical type memory cell transistor is connected to a gate driver transistor.

10. The semiconductor memory device according to claim 9, wherein the characteristic change element comprises a phase change film.

11. The semiconductor memory device according to claim 10, wherein the phase change film is made of GST, AsSbTe or SeSbTe.

12. The semiconductor memory device according to claim 9, wherein the characteristic change element comprises a resistance change film.

13. The semiconductor memory device according to claim 12, wherein the resistance change film is transition metal oxide film including nickel oxide, niobate oxide, copper oxide, hafnium oxide or zirconium oxide, or a perovskite-type oxide film doped with transition metal.

14. The semiconductor memory device according to claim 9, wherein the vertical type memory cell transistor and the vertical type select transistor comprise a normally-on type MOS transistor or normally-on type MIS transistor.

15. A method of manufacturing a semiconductor memory device including a plurality of memory cells stacked in layers formed on a semiconductor substrate, each of the memory cells being composed of a characteristic change element and a vertical type memory cell transistor connected in parallel to each other, comprising:
forming a plurality of stacked film structures on a surface of a semiconductor substrate, each including a first silicon film and an interlayer insulating film, and selectively etching the stacked film structures to form an opening in the stacked film structures;
etching sides of the first silicon films exposed in the opening to retreat the sides of the first silicon films from sides of the interlayer insulating films;
forming gate insulating films on the retreated sides of the first silicon films;
forming a second silicon film, an anti-reaction film, a characteristic change film and a first insulating film in the order, after the forming of the gate insulating films;
polishing the first insulating film, the characteristic change film, the anti-reaction film and the second silicon film above the surface of the semiconductor substrate to form the first insulating film, the characteristic change film, the anti-reaction film and the second silicon film embedded in the opening;
etching back an uppermost interlayer insulating film by a predetermined thickness to expose upper surfaces of the second silicon film and the characteristic change film; and
forming a third silicon film on the exposed second silicon film and the characteristic change film.

16. The method of manufacturing a semiconductor memory device, according to claim 15, wherein the characteristic change element comprises a phase change film.

17. The method of manufacturing a semiconductor memory device, according to claim 16, wherein the phase change film is made of GST, AsSbTe or SeSbTe, and the anti-reaction film is made of a silicon nitride film having a thickness of about 1 nm.

18. The method of manufacturing a semiconductor memory device, according to claim 15, wherein the characteristic change element comprises a resistance change film.

19. The method of manufacturing a semiconductor memory device, according to claim 18, wherein the resistance change film is transition metal oxide film including nickel oxide, niobate oxide, copper oxide, hafnium oxide or zirconium oxide, or a perovskite-type oxide film doped with transition metal, and the anti-reaction film is a silicon nitride film having a thickness of about 1 nm.

20. The method of manufacturing a semiconductor memory device, according to claim 15, wherein
in forming the second silicon film, the anti-reaction film, the characteristic change film and the first insulating film in the order, the second silicon film, the anti-reaction film, the characteristic change film, the first insulating film and a heat sink film are formed in the order;
in polishing the first insulating film, the characteristic change film, the anti-reaction film and the second silicon film above the surface of the semiconductor substrate, the heat sink, the first insulating film, the characteristic change film, the anti-reaction film and the second silicon film above the surface of the semiconductor substrate are polished to form the heat sink, the first insulating film, the characteristic change film, the anti-reaction film and the second silicon film embedded in the opening;
the heat sink film is etched back to retreat an upper surface of the heat sink film;
a second insulating film is embedded on the retreated upper surface of the heat sink film; and
in etching back the uppermost interlayer insulating film to expose upper surfaces of the second silicon film and the characteristic change film, the uppermost interlayer insulating film and the second insulating film are etched back by the predetermined thickness to expose upper surfaces of the second silicon film and the characteristic change film.
